(19) United States
(12) Patent Application Publication
(10) Pub. No.: US 2025/0374446 A1
(43) Pub. Date: Dec. 4, 2025

(54) FLEXIBLE DISPLAY MODULE

(71) Applicant: Lenovo (Beijing) Limited, Beijing (CN)

(72) Inventors: Yan CHEN, Beijing (CN); Feijun WENG, Beijing (CN)

(21) Appl. No.: 19/222,693

(22) Filed: May 29, 2025

(30) Foreign Application Priority Data
May 31, 2024 (CN) 202410704151.9

(51) Int. Cl. H05K 5/02

(52) U.S. Cl. CPC H05K 5/02

(57) ABSTRACT

A flexible display module includes a display layer and a substrate layer. The substrate layer is attached to the display layer and includes a bending area in the middle, two transition areas arranged on two sides of the bending area, and two non-bending areas on outer sides of the two transition areas. A strip-shaped target through-hole is formed in a transition area and has a length-to-width ratio greater than 50:1. The target through-hole deforms in response to the flexible display module bending.

### CROSS-REFERENCE TO RELATED APPLICATION

The present disclosure claims priority to Chinese Patent Application No. 202410704151.9, filed on May 31, 2024, the entire content of which is incorporated herein by reference.

### TECHNICAL FIELD

The present disclosure relates to the flexible electronic device technology field and, more particularly, to a flexible display module.

### BACKGROUND

Electronic devices with flexible and bendable members, such as flexible electronic screens for cell phones or tablets, may have screen failure or reduced lifespan due to excessive bending stress during the bending process. For example, content cannot be displayed, and the screen can crack and delaminate. Micro-mesh holes are arranged on an ultra-thin stainless steel substrate in an existing flexible electronic screen, and the problems of screen cracking and delamination, and display failure have not been effectively solved. Thus, during the bending process, the screen failure may appear with a high probability.

As shown in FIG. 1, for a flexible screen having a plastic display layer, micro-mesh holes are arranged on the ultra-thin stainless steel substrate, the length of each micro hole of the mesh holes is 2 mm, and a diameter of the hole is 0.15 mm. After the internal stress is released during bending, the maximal internal stress received by the micro holes in the stainless steel substrate can be about 1694.4 MPa. When the size of the display layer increases, the internal stress generated during bending increases too. Thus, the short lifespan of the flexible and bendable member limits the application of the electronic device and compromises the user experience.

### SUMMARY

An aspect of the present disclosure provides a flexible display module, including a display layer and a substrate layer. The substrate layer is attached to the display layer and includes a bending area in the middle, two transition areas arranged on two sides of the bending area, and two non-bending areas on outer sides of the two transition areas. A strip-shaped target through-hole is formed in a transition area and has a length-to-width ratio greater than 50:1. The target through-hole deforms in response to the flexible display module bending.

### BRIEF DESCRIPTION OF THE DRAWINGS

FIG. 1 illustrates a schematic diagram of a bending simulation experiment result of a micro mesh flexible display module according to some embodiments of the present disclosure.

FIG. 2 illustrates a schematic side view diagram of a flexible display module according to some embodiments of the present disclosure.

FIG. 3 illustrates a schematic structural diagram of a substrate layer of a flexible display module according to some embodiments of the present disclosure.

FIG. 4 illustrates a schematic diagram of a bending simulation experiment result of a flexible display module having a sickle-shaped target through-hole according to some embodiments of the present disclosure.

FIG. 5 illustrates a schematic diagram of a bending simulation experiment result of a flexible display module having a golf-shaped target through-hole according to some embodiments of the present disclosure.

FIG. 6 illustrates a schematic diagram of a bending simulation experiment result of a flexible display module having a locomotive-shaped target through-hole according to some embodiments of the present disclosure.

FIG. 7 illustrates a schematic diagram of another bending simulation experiment result of a flexible display module having a locomotive-shaped target through-hole according to some embodiments of the present disclosure.

FIG. 8 illustrates a schematic diagram of another bending simulation experiment result of a flexible display module having a locomotive-shaped target through-hole according to some embodiments of the present disclosure.

FIG. 9 illustrates a schematic diagram of another bending simulation experiment result of a flexible display module having a sickle-shaped target through-hole according to some embodiments of the present disclosure.

FIG. 10 illustrates a schematic diagram of a bending simulation experiment result of a flexible display module with different inner and outer contour curvatures according to some embodiments of the present disclosure.

FIG. 11 illustrates a schematic structural diagram of a through-hole arrangement having a target through hole with a droplet-shaped end according to some embodiments of the present disclosure.

FIG. 12 illustrates a schematic structural diagram showing two rows of through holes having different end shapes according to some embodiments of the present disclosure.

FIG. 13 illustrates a schematic structural diagram of a through hole arrangement having a specific through hole according to some embodiments of the present disclosure.

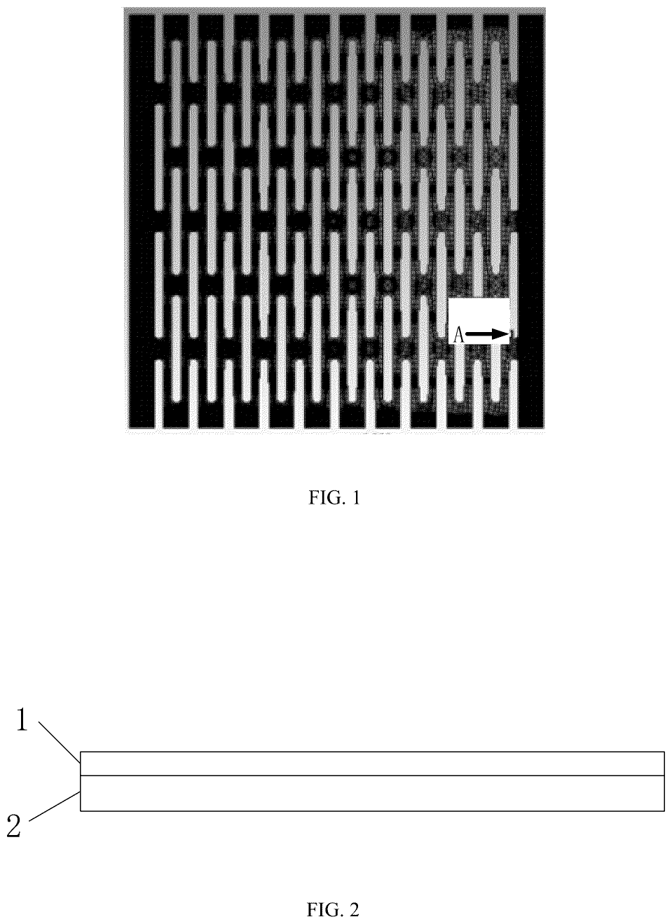

### DETAILED DESCRIPTION OF THE EMBODIMENTS

To enable those skilled in the art to better understand the technical solutions of the present disclosure, the present disclosure is described in detail in connection with the accompanying drawings and specific embodiments. Embodiments of the present disclosure are further described in detail below in conjunction with the accompanying drawings and specific embodiments, which shall not be considered as limiting the present disclosure.

The terms “first,” “second,” and similar words used in the present disclosure do not represent any order, quantity, or importance but are merely used for distinction. Terms such as “comprising” or “including” mean that an element preceding these terms encompasses elements listed after these terms and do not exclude the possibility of also encompassing other elements.

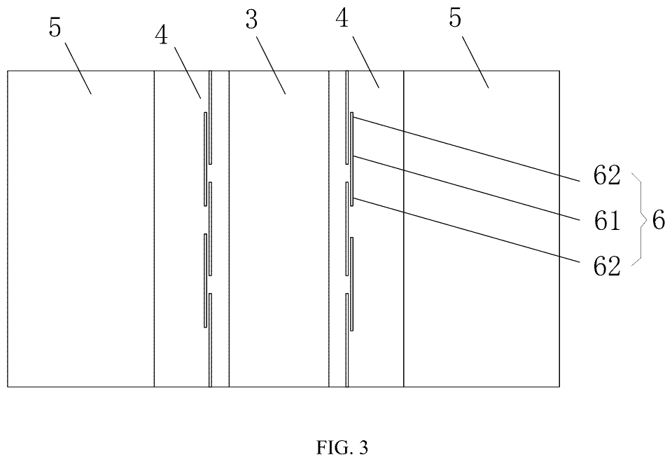

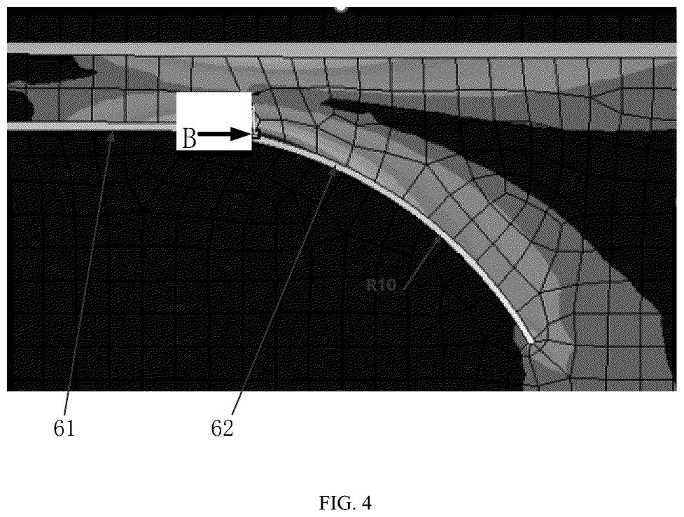

As shown in FIGS. 2 and 3, embodiments of the present disclosure provide a flexible display module. The flexible display module includes a substrate layer 1 and a display layer 2. The substrate layer 1 is attached to the display layer 2. The substrate layer 1 includes a bending area 3 arranged in the middle, two transition areas 4 arranged on two sides of the bending area 3, and two non-bending areas 5 arranged on outer sides of the two transition areas 4. A strip-shaped target through-hole 6 is formed in the transition area 4. The length-to-width ratio of the target through-hole 6 can be greater than 50:1. When the flexible display module bends, the target through-hole 6 can deform.

As shown in FIG. 2, the substrate layer 1 is attached to the display layer 2. That is, the substrate layer 1 is connected to the display layer 2 in a stacked manner. When the flexible display module bends, the positions of the display layer 2 corresponding to the bending area 3 and the transition areas 4 of the substrate layer 1 can bend. Meanwhile, the bending area 3 and the transition areas 4 of the substrate layer 1 can bend. The transition areas 4 are arranged between the bending 3 and the non-bending areas 5. The non-bending areas 5 may not bend when the flexible display module bends. The bending degrees of the two transition areas 4 can be different from the bending degree of he bending area 3.

As shown in FIG. 3, in some embodiments, the arrangement direction of the target through-hole 6 is perpendicular to the bending direction. The target through-hole 6 includes a body member 61 and end members 62 on two sides of the body member 61. The body member 61 includes a middle member and transition members on two sides of the middle member. At least an extension direction of the transition members of the body member 61 is perpendicular to the bending direction. That is, only the extension direction of the transition member is perpendicular to the bending direction, an extension direction of the whole body member 61 is perpendicular to the bending direction, or an extension direction of the whole target through hole 6 is perpendicular to the bending direction. Thus, when the flexible display module bends, the target through hole 6 can deform in the bending direction to increase the width of the hole.

The target through-hole 6 can be arranged in the transition area 4. The bending direction of the flexible display module can be the direction from the bending area 3 toward the non-bending area 5. After bending along the bending direction, the two non-bending areas 5 can face each other, and the two transition areas 4 can face each other. The arrangement direction of the whole target through-hole 6 can be perpendicular to the bending direction. That is, the length direction of the target through-hole 6 is perpendicular to the bending direction, while the width direction of the through-hole 6 can align with the bending direction.

The length-to-width ratio of the target through-hole 6 can be greater than 50:1. That is, the length of the through-hole is 50 times greater than the width, and the length is significantly greater than the width. When the flexible display module bends, the target through-hole 6 in the transition area 4 can be subjected to a pulling force and can deform. Along the bending direction, a distance between two long edges of the target through-hole 6 can increase, and a corresponding displacement can be generated. According to the force or bending, the target through-hole 6 can change to different types of ellipses to provide a sufficient bending displacement. Thus, the internal stress concentrated in the transition areas 4 and the bending area 3 when the display layer 2 bends can be greatly released. Thus, the cracking and delamination at the positions of the display layer 2 corresponding to the transition areas 4 and the bending area 3 can be avoided. The problems of the failure of the display layer 2 due to the excessive internal stress can be solved for the flexible display module during the bending process. Meanwhile, the lifespan of the bendable flexible display module can be improved, and the user experience can be improved.

In some embodiments, the substrate layer 1 can be made of stainless steel. The ultra-thin stainless steel substrate layer 1 can be flexible and bend. The ultra-thin stainless steel substrate layer 1 can support the display layer 2 and can help the display layer 2 recover to the original shape of the display layer 2 after transitioning from the bending status to the flat status.

In some embodiments, the display layer 2 can be made of plastic. The display layer 2 can be made of a plurality of plastic film layers bonded with adhesive. The flexible display module of the present disclosure can significantly reduce the internal stress at the portions of the display layer 2 corresponding to the transition areas 4 and bending area 3, which can effectively prevent delamination or cracking in the multi-layered display layer 2.

In some embodiments, the flexible display module can be applied to the flexible electronic screen to solve the problems of the screen failure due to the large internal stress of the electronic screen during the bending process and the low lifespan.

In some embodiments, the target through-hole 6 can have a hole width of 0.1-2 mm and a hole length of 50-200 mm. Based on a length-to-width ratio greater than 50:1, the target through-hole 6 can have a hole width of 0.15 mm and a hole length of 100 mm, or a hole width of 0.15 mm and a hole length of 80 mm, or a hole width of 0.3 mm and a hole length of 80 mm. A plurality of values can be provided for the hole width and the hole length of the target through-hole 6, and can be set according to the width and material of the flexible screen module to obtain an appropriate effect of releasing the internal stress.

In some embodiments, the target through-hole 6 can include a body member 61 and two end members 62. The body member 61 of the target through-hole 6 can be arranged between the two end members 62 of the target through-hole 6. The two end members 62 of the target through-hole 6 can extend toward the bending area 3 relative to the body member 61 of the target through-hole 6. Through a simulation experiment, when the flexible display module bends, the end members 62 of the target through-hole 6 can bear the maximum internal stress. By configuring the end members 62 of the target through-hole 6 to extend toward the bending area 3 relative to the body member 61, the internal stress received by the end members 62 of the target through-hole 6 can be greatly reduced during bending after a large portion of the internal stress is released. Thus, the cracking due to stress concentration of the end members 62 can be prevented, and the lifespan of the substrate layer 1 can be improved.

In some embodiments, the two end members 62 of the target through-hole 6 can extend into an arc shape. Through the simulation experiment, the positions where the stress concentration is distributed can be obtained at the end members 62 of the target through-hole 6. As shown in FIG. 4, the end members 62 of the target through-hole 6 are configured in a sickle-like arc shape. The end members 62 can have the same hole distance as the body member 61, and have a bending radius of 10 mm. The internal stress received by the end members 62 can range from 85 to 383.02 MPa. When the position is closer to the target through-hole 6, the internal stress can be larger. The internal stress received by the body member 61 can range from 0.001 to 85 MPa. When the position is closer to the target through-hole 6, the internal stress can be larger. At position B, the end member 62 can receive the maximum internal stress of 383.02 MPa. The end member 62 of the target through-hole 6 can have a larger internal stress than the body member 61. By configuring the end member 62 of the target through-hole 6 in an arc shape, the internal stress received by the end member 62 of the target through-hole 6 can be reduced after the large portion of the internal stress is released during bending compared to the situation when the end member 62 and the body member 61 have the same extension direction. Thus, the cracking due to the stress concentration of the end member 62 can be prevented, and the lifespan of the substrate layer 1 can be improved.

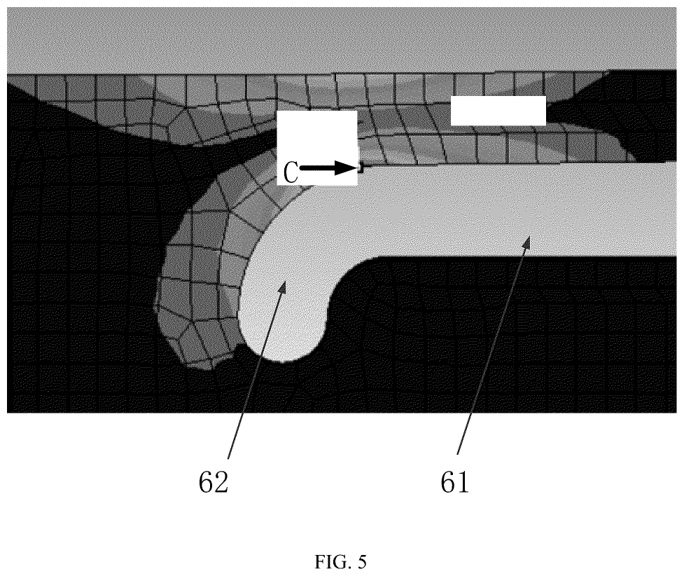

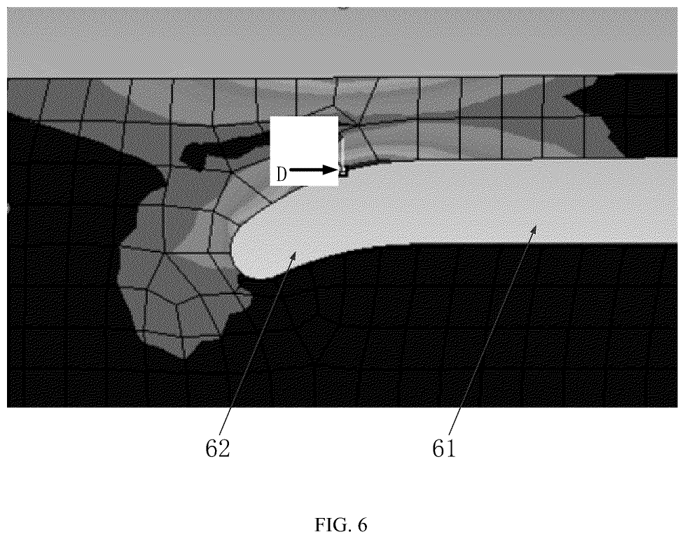

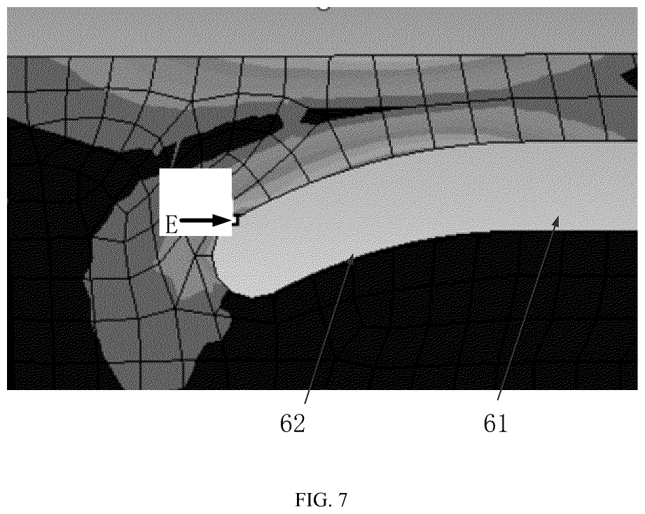

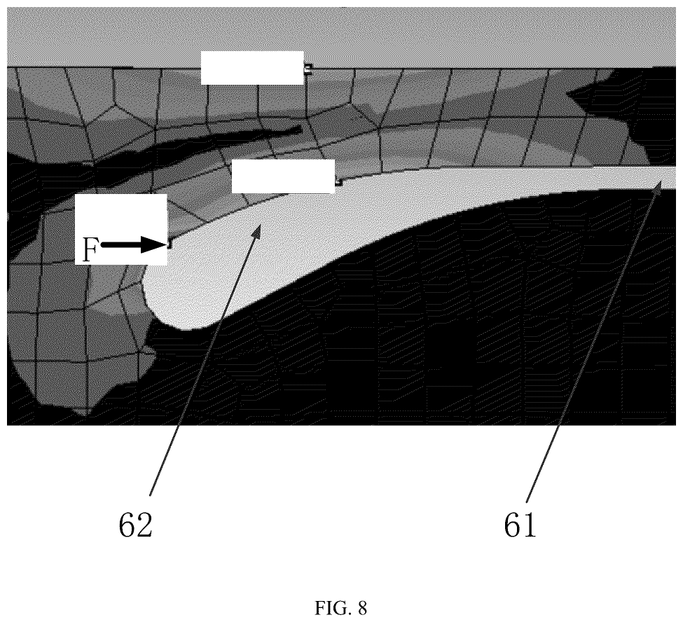

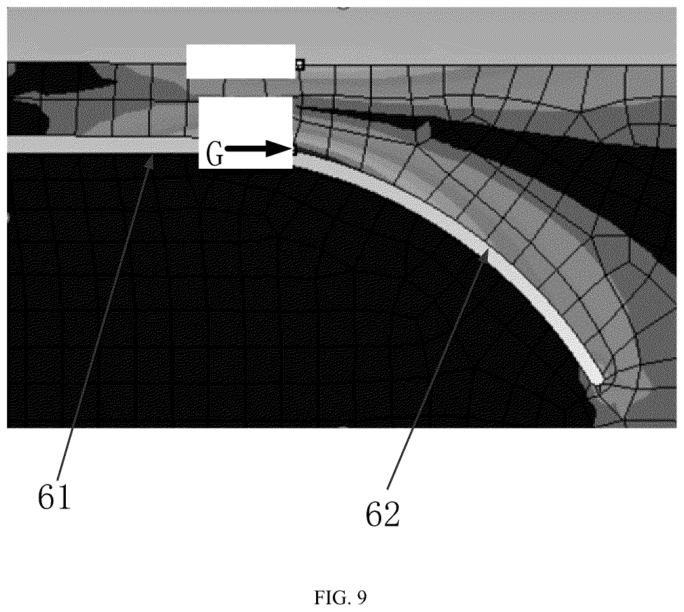

In some embodiments, the bending radius of the end member 62 of the target through-hole 6 that extends in an arc shape can be 3-20 mm, e.g., 10 mm, 8 mm, or 5 mm. Different bending radii can correspond to end members 62 of different bending degrees and different shapes. Thus, target through-holes 6, adapting to different internal stresses, can be obtained. The end members 62 of different shapes can be subjected to different internal stress distributions. With the target through-hole 6 of the present disclosure, the internal stress received by the end member 62 can be reduced. FIG. 5 illustrates the bending simulation process. After the large portion of the internal stress is released during bending, at position C, the end member 62 can receive the maximum internal stress of 580.39 MPa. As shown in FIG. 6, an outer arc bending radius is 10 mm. After the large portion of the internal stress is released during bending, at position D, the end member 62 can receive the maximum internal stress of 465.23 MPa. As shown in FIG. 7, the bending radius is 10 mm. After the large portion of the internal stress is released during bending, at position E, the end member 62 can receive the maximum internal stress of 457.11 MPa. As shown in FIG. 8, the outer arc bending radius is 10 mm, and the hole width of the end member is 0.3 mm. After the large portion of the internal stress is released during bending, at position F, the end member 62 can receive the maximum internal stress of 487.63 MPa. As shown in FIG. 9, the bending radius is 10 mm, and the hole width of the end member is 0.3 mm. After the large portion of the internal stress is released, at position G, the end member 62 can receive the maximum internal stress of 374.79 MPa. Thus, according to the materials of the substrate layer 1 and the display layer 2, and the requirement of releasing the internal stress, the end members 62 of different shapes can be selected.

In some embodiments, the target through-hole 6 includes a body member 61 and two end members 62. The body member 61 of the target through-hole 6 can be arranged between the two end members 62 of the target through-hole 6. The hole width of the two end members 62 of the target through-hole 6 can be different from the hole width of the body member 61 of the target through-hole 6. The hole width of the two end members 62 can be greater or smaller than the hole width of the body member 61. The target through-hole of FIG. 6 and the target through-hole of FIG. 8 have the same bending radius and different hole widths. In the simulation experiment, after the large portion of the internal stress is released during bending, the end member 62 of the target through-hole 6 of FIG. 6 and the end member 62 of the target through-hole 6 of FIG. 8 can have different maximum internal stresses. For the end members 62 with the same bending radius and different hole widths, the end members 62 can receive different maximum internal stresses after the internal stress is released during bending. Thus, according to the materials of the substrate layer 1 and the display layer 2, and the requirement of releasing the internal stress, the end members 62 with different hole widths can be selected.

For the two different types of target through-holes 6, the end member 62 can extend toward the bending area 3 relative to the body member 61, or the end member 62 can have the same extension direction as the body member 61. The hole width of the two end members 62 of the target through-hole 6 can be different from the hole width of the body member 61.

In some embodiments, the curvature of the outer contour of the end member 62 of the target through-hole 6 away from the bending area 3 can be different from the curvature of the inner contour line of the end member 62 close to the bending area 3. For the two different types of target through-holes 6 with the end member 62 extending toward the bending area 3 relative to the body member 61 or the end member 62 of the target through-hole 6 having the same extension direction as the body member 61, the curvature of the outer contour of the end member 62 of the target through-hole 6 away from the bending area 3 can be different from the curvature of the inner contour of the end member 62 of the target through-hole 6 close to the bending area 3. For the target through-hole 6 having the end member 62 extending toward the bending area 3 relative to the body member 61, the curvature of the outer contour can be smaller or greater than the curvature of the inner contour. That is, the bending degrees of the outer contour and the inner contour can be different.

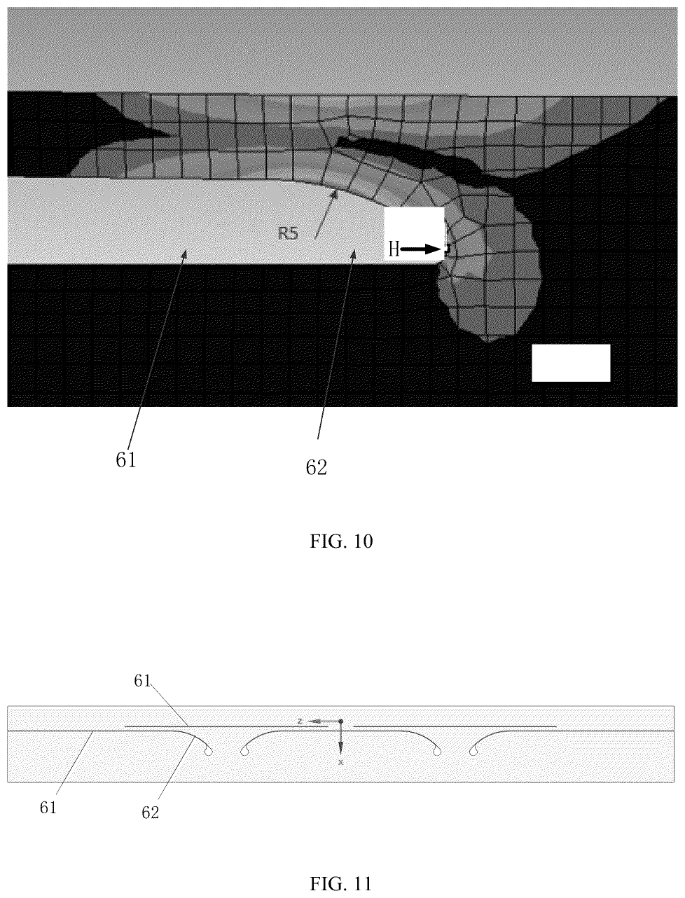

For example, as shown in FIG. 10, the end member 62 and the body member 61 of the target through-hole 6 can have the same extension direction. The inner contour of the end member 62 of the target through-hole 6, close to the bending area 3, is consistent with the extension direction of the body member 61. The outer contour of the end member 62, away from the bending area 3, is in an arc shape and has a bending radius of 5 mm. Thus, the end member 62 is similar to a locomotive shape. Through the bending simulation experiment, after the end member 62 of the target through-hole 6 of FIG. 10 releases the large portion of the internal stress, at position H, the end member 62 receives the maximum internal stress of 572.79 MPa. The extension directions of the body member 61 and the end member 62 of the target through-hole 6 of FIG. 6 are perpendicular to the bending direction. Compared to the design in which the end member 62 and the body member 61 of the target through-hole 6 have the same extension direction, and the curvature of the outer contour away from the bending area 3 is the same as the curvature of the inner contour close to the bending area 3, the internal stress received by the end member 62 during bending can be effectively reduced.

In some embodiments, the end member 62 of the target through-hole 6 can form a droplet shape. For the two different types of target through-holes 6 with the end member 62 extending toward the bending area 3 relative to the body member 61 or having the same extension direction as the body member 61, the arc-shaped end member 62 can be formed into the droplet shape.

FIG. 11 illustrates the target through-hole 6 with the end member 62 extending toward the bending area 3 relative to the body member 61. The arc-shaped end member 62 is formed into a droplet shape. Compared to the end member 62 extending toward the bending area 3 relative to the body member 61 without the droplet shape, the internal stress received by the end member 62 of the target through-hole 6 can be reduced after the large portion of the internal stress is released during bending. For the target through-hole 6 with the end member 62 and the body member 61 having the same extension direction, the end member 62 of the target through-hole 6 can be formed into a droplet shape. Compared to the target through-hole 6 with the end member 62 not in the droplet shape, the internal stress received by the end member 62 of the target through-hole 6 can be reduced during bending.

In some embodiments, each transition area 4 can include at least two rows of through-holes. One or a plurality of through-holes can be provided for any row of through-holes in the transition area 4. Each transition area 4 can include at least two through-holes that are the target through-holes 6, only one of the at least two through-holes that is the target through-hole 6, or a part of the through-holes 6 that are the target through-holes 6. Two or more rows of through-holes can be provided in the transition area 4 to better release the internal stress in the transition area 4 and the bending area 3. The number of the target through-holes 6 can be set as needed. With more target through-holes 6, the capability of indirectly releasing the internal stress at the positions of the display layer 2 corresponding to the transition area 4 and the bending area 3 can be improved.

In some embodiments, when the transition area 4 includes only one target through-hole 6 or a plurality of target through-holes 6, the one target through-hole 6 or the plurality of target through-holes 6 can be distributed only in any one row of through-holes. When the transition area 4 includes a plurality of target through-holes 6, the plurality of target through-holes 6 can be distributed in different rows of through-holes, or arbitrarily distributed in a part of rows of through-holes. Thus, the flexible display module can release the internal stress of the display layer 2 indirectly during bending.

In some embodiments, if a part of the at least two through-holes of the transition area 4 is the target through-holes 6, the other through-holes of the at least two through-holes, except for the target through-holes 6, in the transition area 4 can be the non-target through-holes. The length-to-width ratio of the non-target through-holes 6 can be smaller than or equal to 50:1. When the at least two through-holes are ensured to have the target through-holes 6, the substrate layer 1 can indirectly release the bending internal stress of the display layer 2 when the flexible display module bends, although the non-target through-holes 6 exist.

In some embodiments, a first row of through-holes and a second row of through-holes that are neighboring to each other can be arranged in each transition area 4. The through-hole end members 62 of the first row of through-holes and the second row of through-holes can have the same shape. For example, the through-hole end members 62 of the first row of through-holes can extend toward the bending area 3 relative to the body member 61 of the through-hole, and the through-hole end members 62 of the second row of through-holes can also extend toward the bending area 3 relative to the body member 61 of the through-hole. For another example, the end member 62 of the first row of through-holes and the end member 62 of the second row of through-holes can have the same extension direction as the body member 61.

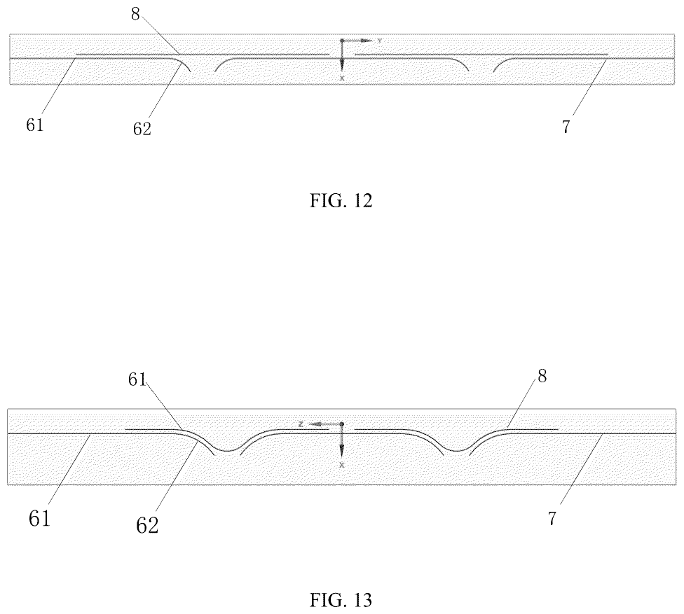

In some embodiments, the first row of through-holes and the second row of through-holes that are neighboring to each other can be arranged in each transition area 4. The end members 62 of the first row of through-holes 7 and the end members 62 of the second row of through-holes can have different shapes. As shown in FIG. 12, for example, direction X represents the bending direction, direction Y represents a direction perpendicular to direction X. The through-hole end members 62 of the first row of through-holes 7 extend toward the bending area 3 relative to the body member 61 of the through-hole. The through-hole end members 62 of the second row of through-holes 8 do not extend toward the bending area 3 relative to the body member 61 of the through-hole. That is, only the end members 62 of the second row of through-holes 8 can extend to form the arc shape. For another example, the arc shape of the end members 62 of the first row of through-holes 7 can be different from the arc shape of the end members 62 of the second row of through-holes 8. That is, the end members 62 of the first row of through-holes 7 and the end members 62 of the second row of through-holes 8 can have different bending radii. When the end members 62 of the first row of through-holes 7 and the end members 62 of the second row of through-holes 8 have different shapes, the internal stress can also be released.

No matter whether the shapes of the end members 62 of the first row of through-holes 7 and the end members 62 of the second row of through-holes 8 are the same, the internal stress of the display layer 2 can be released indirectly when the flexible display module bends.

In some embodiments, the two end members 62 of the target through-hole 6 can extend toward the bending area 3 relative to the body member 61. The target through-hole 6 can be arranged in the first row of through-holes 7. The first row of through-holes 7 can be a row of through-holes close to the bending area 3. By arranging the target through-hole 6 in the first row of through-holes 7 close to the bending area 3, the internal stress of the display layer 2 can be better released when the display layer 2 bends, compared to arranging the target through-hole 6 in the second row of through-holes 8 away from the bending area 3.

In some embodiments, the through-holes can be staggered between the first row of through-holes 7 and the second row of through-holes 8. The second row of through-holes 8 can include a specific through-hole. The specific through-hole can include a body member 61 and two end members 62. The two end members 62 of the specific through-hole can have the same extension direction as the body member 61.

If the first row of through-holes 7 and the second row of through-holes 8 are not staggered but aligned, the distance between two neighboring target through-holes 6 in each row may cause the target through-holes to be unable to be pulled. By arranging the target through-holes 6 of the neighboring rows in a staggered manner, the internal stress can be effectively released.

The specific through-hole can be the target through-hole 6 or a non-target through-hole. That is, in the second row of through-holes 8, at least one specific through-hole can be provided with the two end members 62 having the same extension direction as the body member 61.

In some embodiments, the middle member of the specific through-hole can bend in the direction toward the bending area 3. The second row of through-holes 8 can include at least one of such through-holes. Since the first row of through-holes 7 and the second row of through-holes 8 can be staggered. The middle member of the specific through-hole can correspond to the interval position between the two neighboring through-holes of the first row of through-holes 7. That is, the middle bending member can point to the distance between the two neighboring through-holes of the first row of through-holes 7. As shown in FIG. 13, the end members 62 of any one through-holes or two through-holes of the two neighboring through-holes in the first row of through-holes 7 corresponding to the middle bending member of the specific through-hole can have the arc shape (i.e., any one through-hole or two through-holes of the two neighboring through-holes of the first row of through-holes 7 are target through-holes 6). Compared to the end members 62 of any one through-hole or the two through-holes of the two neighboring through-holes of the first row of through-holes 7 have the arc shape, the internal stress received by the end members 62 can be further reduced after a large portion of the internal stress is released during bending. The internal stress at the positions of the display layer 2 corresponding to the transition area 4 and the transition area 3 can be indirectly reduced, and the lifespan of the substrate layer 1 can be increased.

Furthermore, although exemplary embodiments have been described herein, the scope includes any and all embodiments based on the present disclosure with equivalent elements, modifications, omissions, combinations (e.g., cross-embodiments), adaptations, or variations. Elements in the claims are interpreted broadly based on the language used in the claims and are not limited to the examples described in this specification or during the implementation of the present disclosure, which are construed as non-exclusive. Therefore, this specification and these examples are intended to be examples only. The true scope and spirit can be indicated by the full scope of the appended claims and their equivalents.

The above description is intended to be illustrative rather than restrictive. For example, the above examples (or one or more solutions) may be combined with each other. For example, other embodiments may be employed by those of ordinary skill in the art upon reading the above description. Additionally, in some embodiments, various features may be grouped together to simplify the present disclosure, which should not be interpreted as an intention that any unclaimed feature is essential to any claim. On the contrary, the subject matter of the present disclosure may include fewer than all the features of any particular disclosed embodiment. Thus, the following claims can be incorporated into the detailed description as examples or embodiments, with each claim standing independently as a separate embodiment, and these embodiments may be combined with each other in various combinations or permutations. The scope of the present disclosure should be determined with reference to the appended claims and the full scope of equivalents to which such claims are entitled.

The above embodiments are merely exemplary embodiments of the present disclosure and are not intended to limit the present disclosure. The scope of the present disclosure is defined by the claims. Those skilled in the art may make various modifications or equivalent substitutions to the present disclosure within the spirit and scope of the present disclosure. Such modifications or substitutions should be within the scope of the present disclosure.

What is claimed is:

1. A flexible display module comprising:
a display layer; and
a substrate layer attached to the display layer and including a bending area in the middle, two transition areas arranged on two sides of the bending area, and two non-bending areas on outer sides of the two transition areas, a strip-shaped target through-hole being formed in a transition area and having a length-to-width ratio greater than 50:1, and the target through-hole deforming in response to the flexible display module bending.

2. The flexible display module according to claim 1, wherein:
the target through-hole includes a body member and two end members:
the body member is arranged between the two end members; and
the two end members extend toward the bending area relative to the body member.

3. The flexible display module according to claim 2, wherein:
the two end members extend to form an arc shape.

4. The flexible display module according to claim 1, wherein:
the target through-hole includes a body member and two end members;
the body member is arranged between the two end members; and
a hole width of the two end members is different from a hole width of the body member.

5. The flexible display module according to claim 1, wherein:
a curvature of an outer contour of the end member of the target through-hole away from the bending area is different from a curvature of an inner contour of the end member close to the bending area.

6. The flexible display module according to claim 1, wherein the end member of the target through-hole is formed into a droplet shape.

7. The flexible display module according to claim 1, wherein:
each transition area includes a first row of through-holes and a second row of through-holes that are neighboring to each other; and
end members of the first row of through-holes and end members of the second row of through-holes have different shapes.

8. The flexible display module according to claim 7, wherein:
the two end members of the target through-hole extend toward the bending area relative to the body member;
the target through-hole is arranged in the first row of through-holes; and
the first row of through-holes is a row of through-holes closest to the bending area.

9. The flexible display module according to claim 8, wherein:
the first row of through-holes and the second row of through-holes are staggered with each other;
the second row of through-holes include a specific through-hole, including a body member and two end members; and
the two end members of the specific through-hole have a same extension direction as the body member.

10. The flexible display module according to claim 9, wherein a middle member of the specific through-hole bends toward the bending area.
